(19) United States
(12) Patent Application Publication
(10) Pub. No.: US 2023/0120621 A1
(43) Pub. Date: Apr. 20, 2023

(54) MEMORY DEVICE AND METHOD OF FABRICATING THE SAME

(71) Applicant: MACRONIX International Co., Ltd., Hsinchu (TW)

(72) Inventors: Chih-Kai Yang, Kaohsiung City (TW); Tzung-Ting Han, Hsinchu City (TW)

(73) Assignee: MACRONIX International Co., Ltd., Hsinchu (TW)

(21) Appl. No.: 17/505,487

(22) Filed: Oct. 19, 2021

(51) Int. Cl. H01L 27/11582; H01L 23/535; H01L 27/11556; H01L 21/225; H01L 21/768

(52) U.S. Cl. CPC H01L 27/11582; H01L 21/2254; H01L 21/76805; H01L 21/76895; H01L 23/535; H01L 27/11556

(57) ABSTRACT

An embodiment of the present the disclosure provides a memory device, including: a substrate, an interconnection structure disposed on the substrate, a conductive layer disposed on the interconnection structure, a stop layer disposed on the conductive layer, and a gate stack structure disposed on the stop layer. The gate stack structure includes a plurality of insulating layers and a plurality of gate conductive layers that alternate with each other. A ratio of a thickness of a bottommost insulating layer of the gate stack structure to a thickness of the stop layer is 1:1 to 1:2. The memory device further includes a channel pillar extending through the gate stack structure and the stop layer and to electrically connect the conductive layer, and a charge storage structure disposed between sidewalls of the channel pillar and the plurality of gate conductive layers.

### BACKGROUND

### Technical Field

The embodiment of the disclosure relates to a semiconductor device and a method of fabricating the same, and particularly, to a memory device and a method of fabricating the same.

### Description of Related Art

Since a non-volatile memory device (e.g., a flash memory) has the advantage that stored data does not disappear at power-off, it becomes a widely used memory device for a personal computer or other electronics equipment.

Currently, the flash memory array commonly used in the industry includes a NOR flash memory and a NAND flash memory. Since the NAND flash memory has a structure in which memory cells are connected together in series, degree of integration and area utilization thereof are better than those of the NOR flash memory. Thus, the NAND flash memory has been widely used in a variety of electronic products. Besides, to further enhance the degree of integration of the memory device, a three-dimensional NAND flash memory is developed. However, there are still some challenges associated with the three-dimensional NAND flash memory. For example, the threshold voltage of the select gate is difficult to control due to the uneven doping concentration of the channel pillar.

### SUMMARY

The embodiments of the disclosure provide a memory device that may improve the uniformity of the doping concentration of the channel pillar, so as to effectively control the threshold voltage of the select gate.

An embodiment of the present invention provides a memory device, including: a substrate, an interconnection structure disposed on the substrate, a conductive layer disposed on the interconnection structure, a stop layer disposed on the conductive layer, and a gate stack structure disposed on the stop layer. The gate stack structure includes a plurality of insulating layers and a plurality of gate conductive layers that alternate with each other. The memory device further includes a channel pillar extending through the gate stack structure and the stop layer and to electrically connect the conductive layer, and a charge storage structure disposed between sidewalls of the channel pillar and the plurality of gate conductive layers. A ratio of a thickness of a bottommost insulating layer of the gate stack structure to a thickness of the stop layer is 1:1 to 1:2.

An embodiment of the present invention provides a memory device, including: a substrate, an interconnection structure disposed on the substrate, a conductive layer disposed on the interconnection structure, a stop layer disposed on the conductive layer, and a gate stack structure disposed on the stop layer. The gate stack structure includes a plurality of insulating layers and a plurality of gate conductive layers that alternate with each other. A material of the stop layer is different from a material of the conductive layer and a material of the insulating layer. The memory device further includes a channel pillar extending through the gate stack structure and the stop layer and to electrically connect the conductive layer, and a charge storage structure disposed between sidewalls of the channel pillar and the plurality of gate conductive layers.

An embodiment of the present invention provides a method for manufacturing a memory device, including: forming an interconnection structure on a substrate. A first stack structure is formed on the interconnection structure. The first stack structure includes a plurality of first conductive layers and a plurality of first insulating layers that alternate with each other; forming a stop layer on the first stack structure A second stack structure is formed on the stop layer. , The second stack structure includes a plurality of second insulating layers and a plurality of interlayers that alternate with each other. A charge storage structure and channel pillars are formed in the second stack structure, the stop layer and the first stack structure. trench is formed in the second stack structure by using the stop layer as an etching stop layer. The stop layer at a bottom of the trench, the plurality of first insulating layers of the first stack structure, and the first conductive layer between the plurality of first insulating layers are removed to form a first horizontal opening, wherein the first horizontal opening exposes the sidewalls of the channel pillar. A second conductive layer is formed in the first horizontal opening, wherein the second conductive layer is electrically connected to the sidewalls of the channel pillar. The plurality of interlayers of the second stack structure is removed to form multiple second horizontal openings. A plurality of gate conductive layers are formed in the plurality of second horizontal openings. A thermal process is performed to diffuse dopants in the second conductive layer into the channel pillar.

Based on the above, in the embodiment of the disclosure, since the distance between the bottommost gate conductive layer and the conductive layer below the stop layer may be reduced, the dopant in the conductive layer under the gate stack structure may diffuse to the channel pillar corresponding to the bottommost gate conductive layer as the selected gate, so that the selected gate has the desired threshold voltage.

### BRIEF DESCRIPTION OF THE DRAWINGS

FIGS. 1A to 1K are schematic cross-sectional views showing a method for manufacturing a three-dimensional memory device according to an embodiment of the disclosure.

FIG. 2 is a partial enlarged view of FIG. 1K.

FIGS. 3A to 3K are schematic cross-sectional views showing a method for manufacturing a three-dimensional memory device according to an embodiment of the disclosure.

FIG. 4 is a partial enlarged view of FIG. 3K.

### DESCRIPTION OF THE EMBODIMENTS

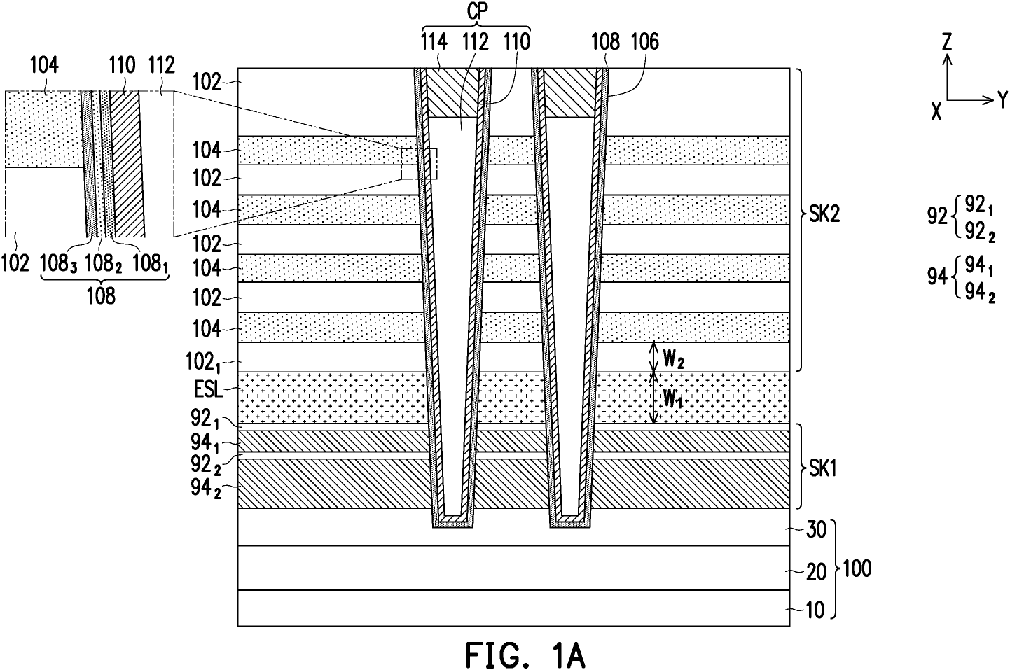

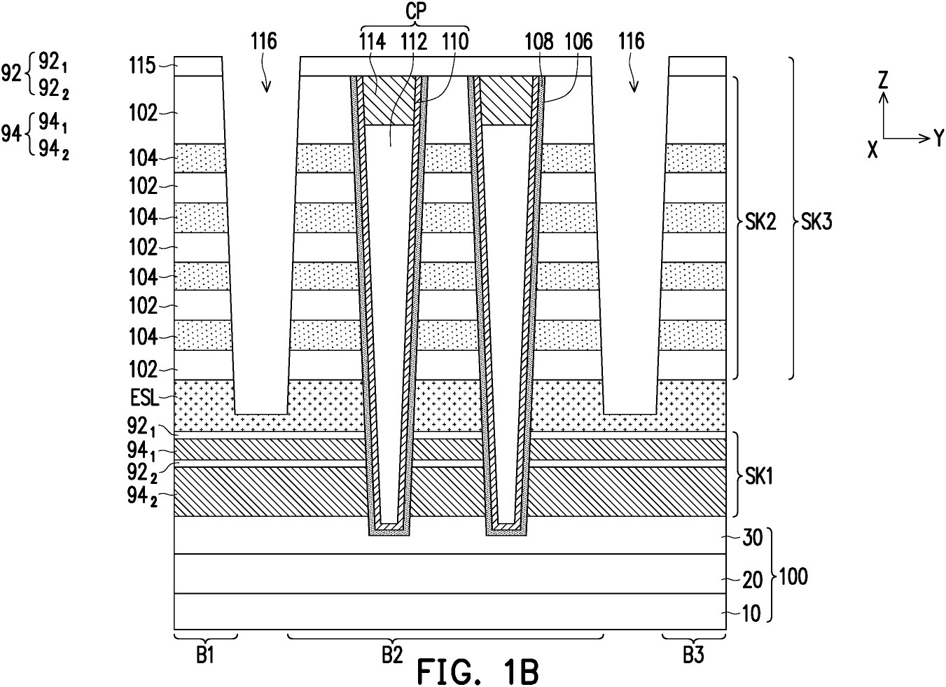

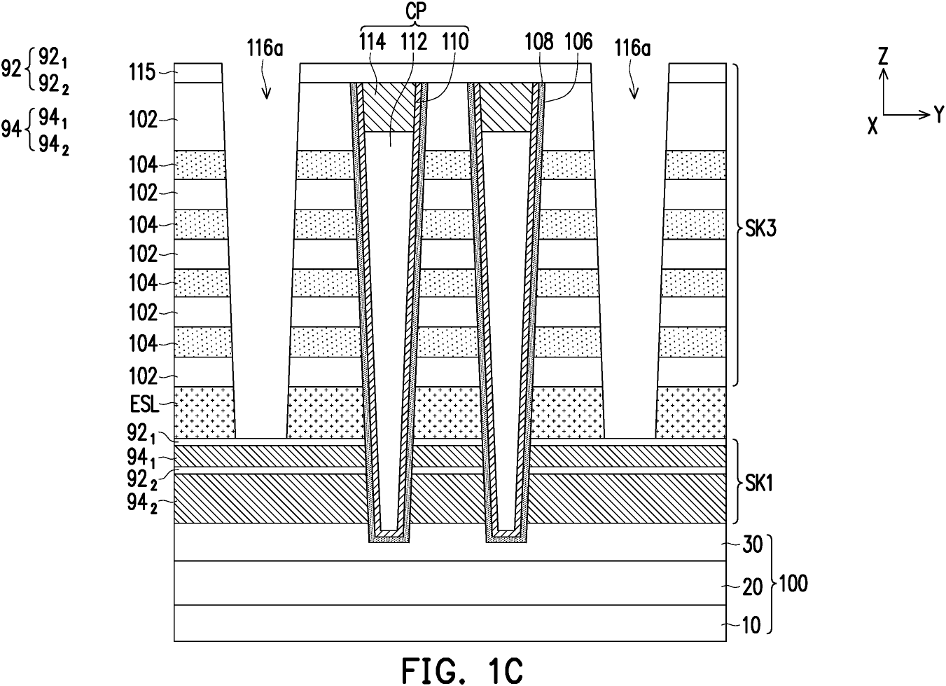

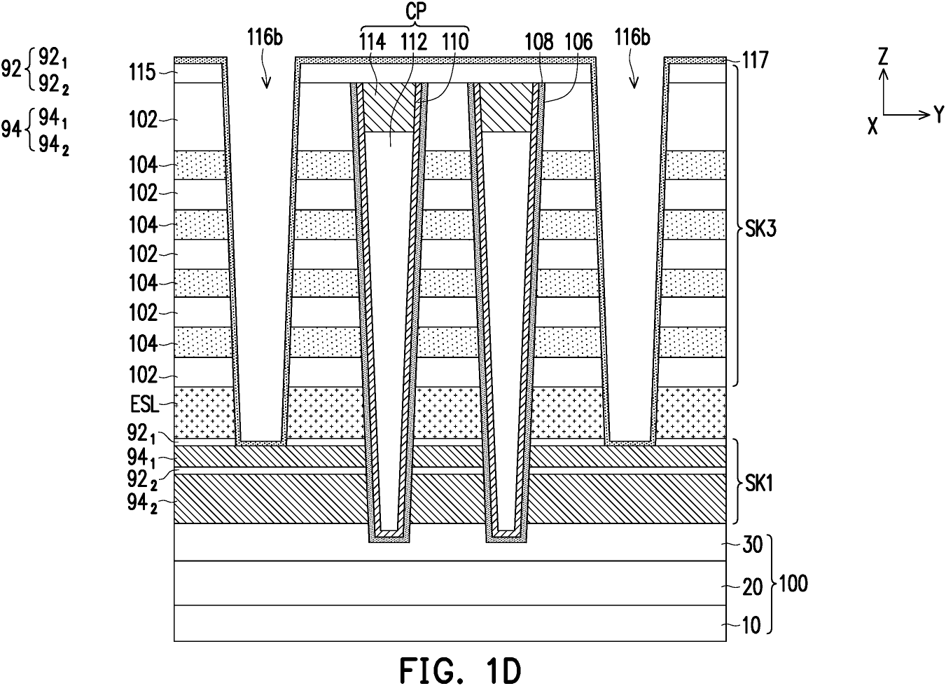

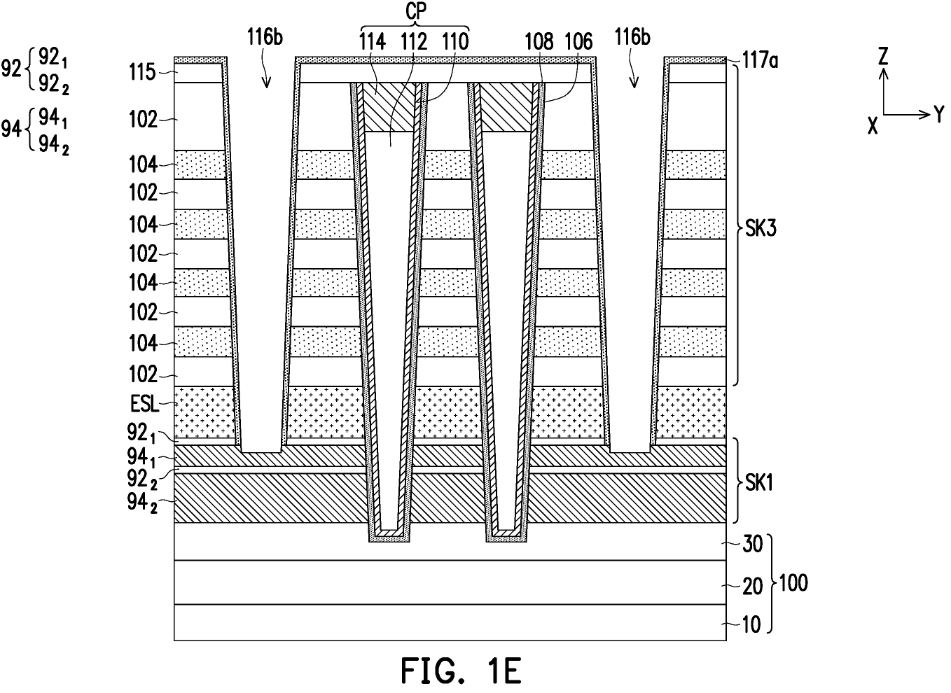

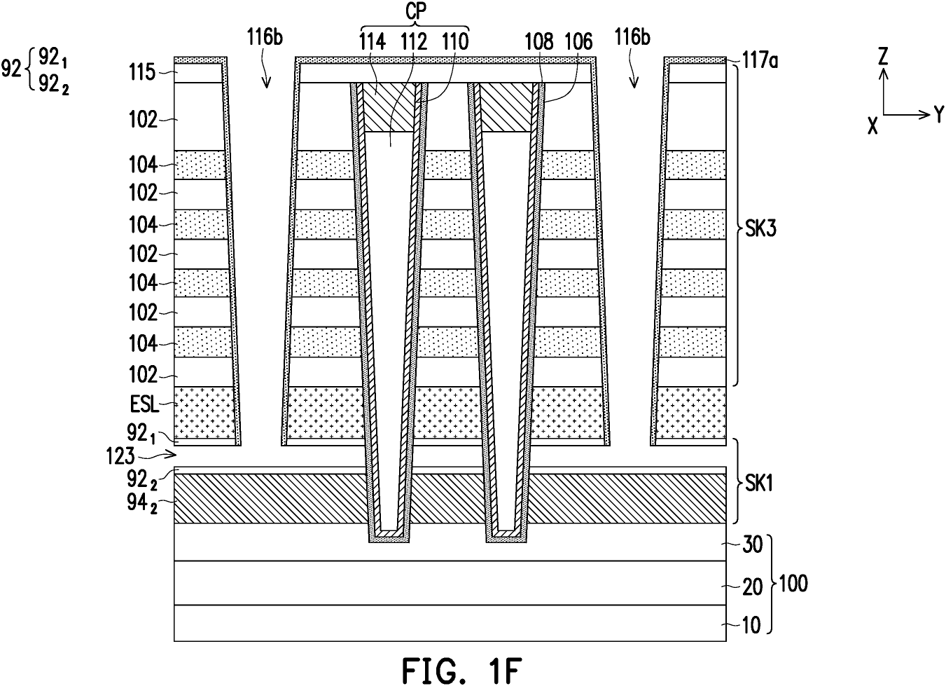

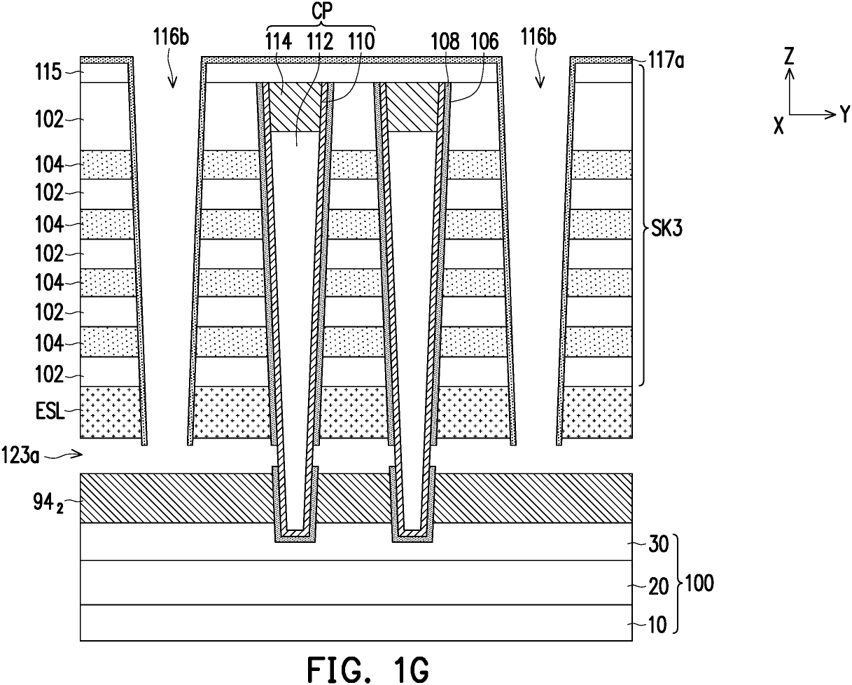

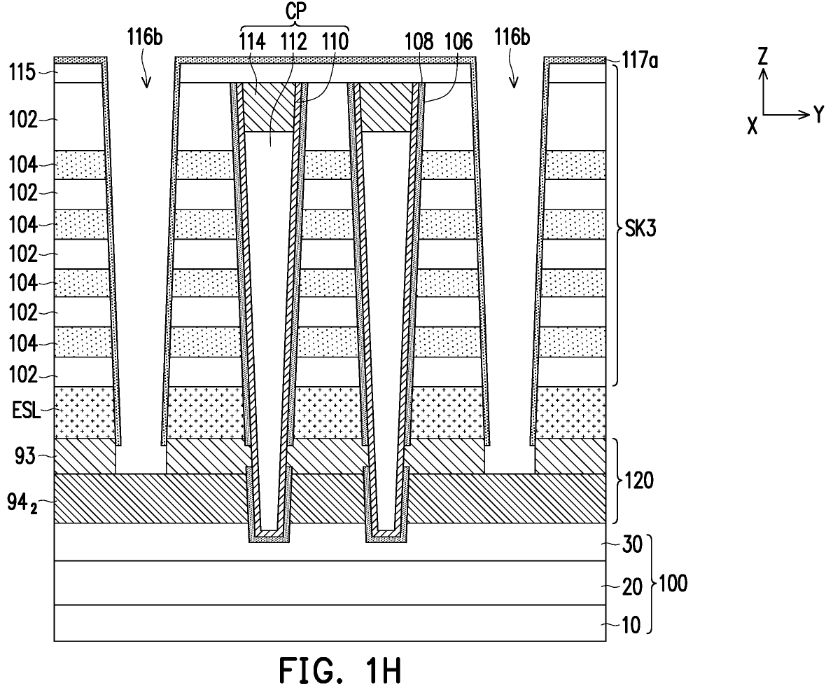

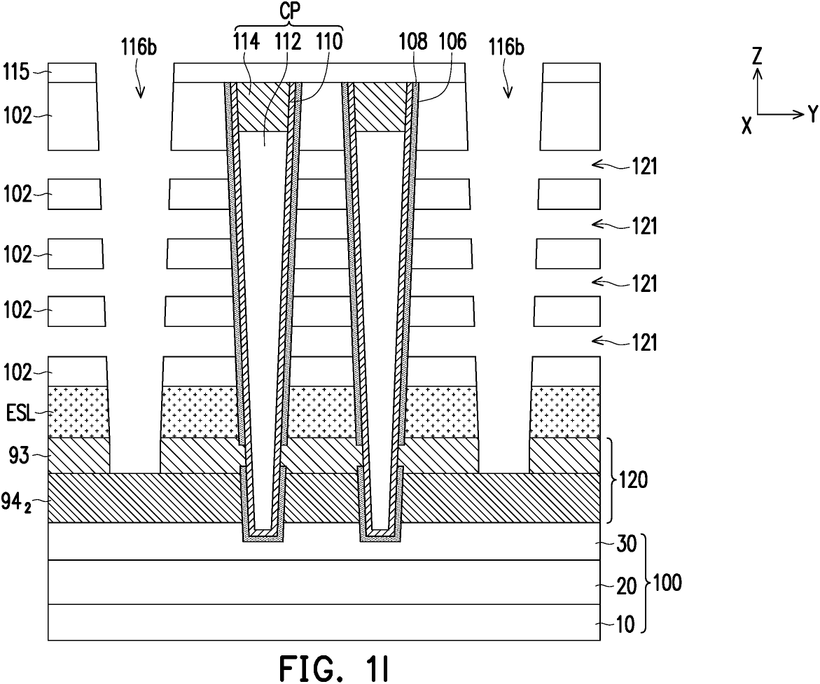

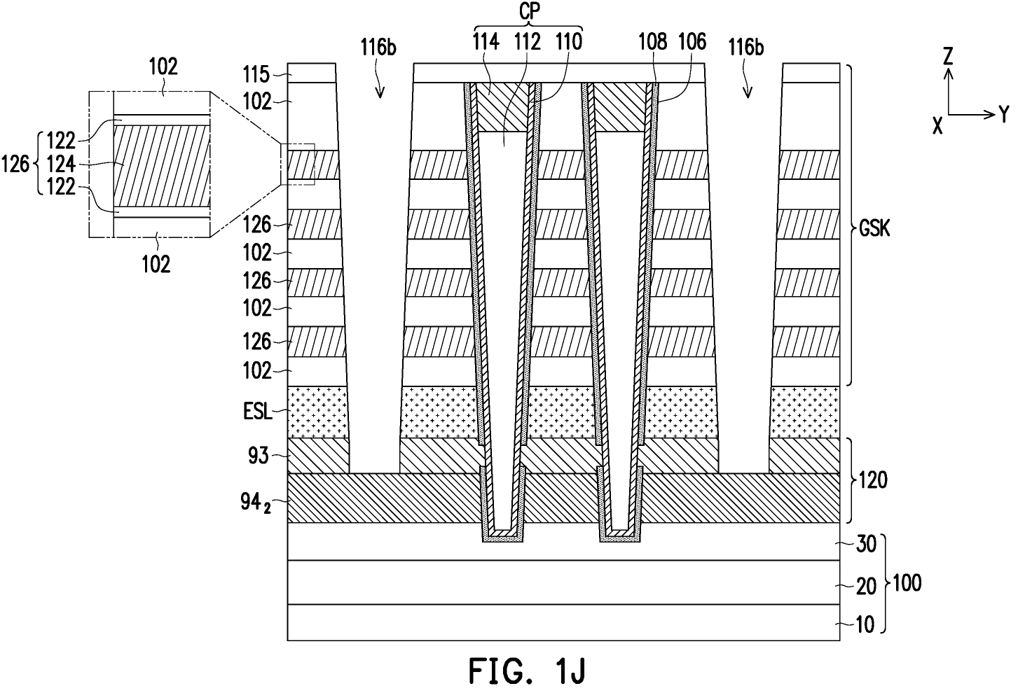

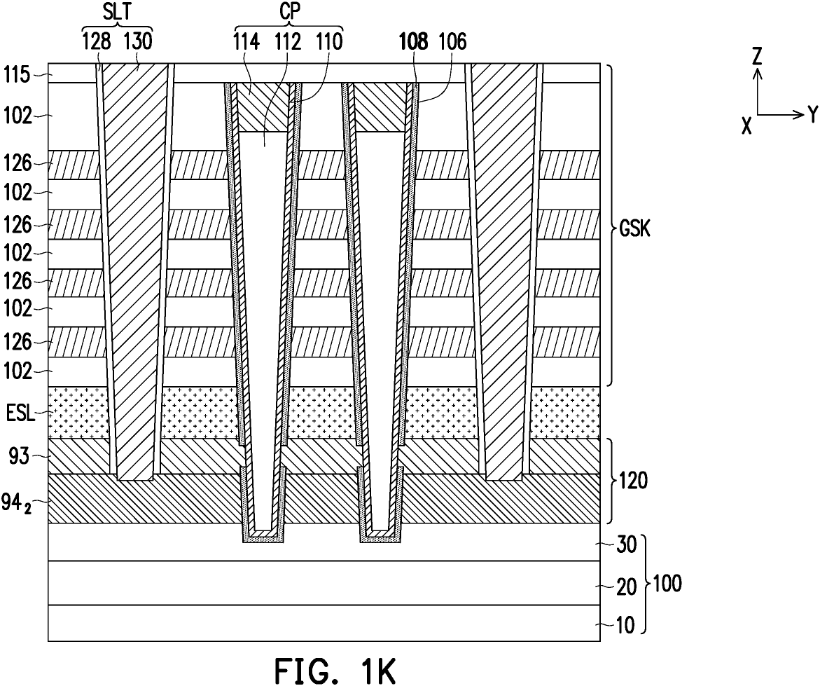

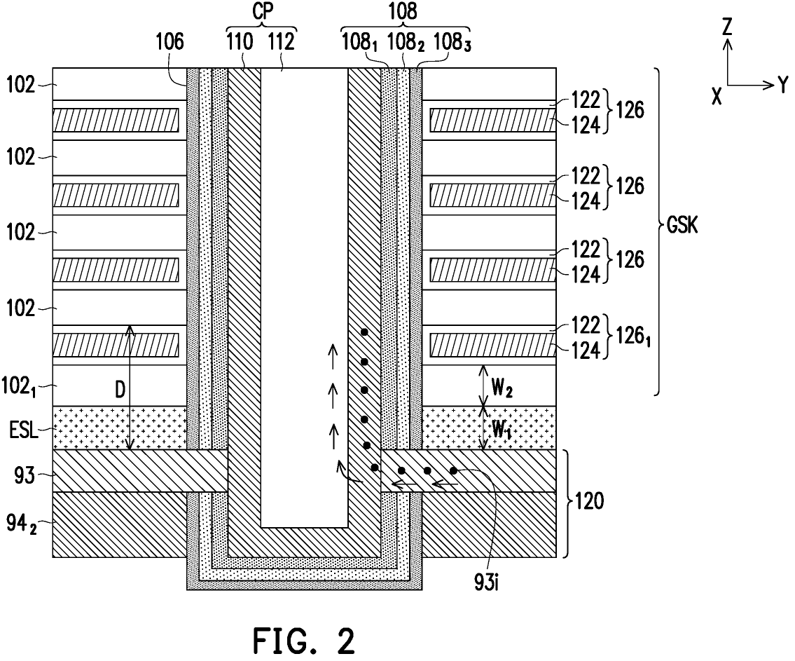

FIGS. 1A to 1K are schematic cross-sectional views showing a method for manufacturing a three-dimensional memory device according to an embodiment of the disclosure. FIG. 2 is a partial enlarged view of FIG. 1K.

Referring to FIG. 1A, a substrate 10 is provided. The substrate 10 may include a semiconductor substrate 10, a device layer 20, and an interconnection structure 30. The semiconductor substrate 10 is, for example, a silicon-containing substrate. The device layer 20 may include an active device or a passive device. The active device is, for example, a transistor, a diode, etc. The passive device is, for example, a capacitor, an inductor, etc. The transistor may be an N-type metal-oxide-semiconductor (NMOS) transistor, a P-type metal-oxide-semiconductor (PMOS) transistor, or a complementary metal-oxide-semiconductor (CMOS). A interconnect structure 30 is formed on the device layer 20. The interconnect structure 30 may include a plurality of dielectric layers and a conductive interconnect formed in the dielectric layers. The conductive interconnect includes a plurality of plugs and a plurality of conductive lines, etc. The dielectric layer separates vertically adjacent conductive lines. The conductive lines may be connected to each other through the plug, and the conductive lines may be connected to the device layer 20 through the plugs. The materials of the plugs and conductive lines include polysilicon or metal comprising copper, tungsten, and aluminum.

A stack structure SK1 is formed on the interconnect structure 30. The stack structure SK1 includes a plurality of insulating layers 92 and a plurality of conductive layers 94 stacked alternately on each other along the Z direction. In an embodiment, the material of the insulating layer 92 includes silicon oxide, and the material of the conductive layer 94 includes doped polysilicon. The dopant of doped polysilicon may include be an element of the group III (e.g., boron) or an element of the group V (e.g., phosphorus). The numbers of insulating layer 92 and conductive layer 94 are not limited to those shown in the figure. Since a memory array will be formed right above the stack structure SK1, and the device layer 20 is, for example, a complementary metal-oxide-semiconductor (CMOS) formed below the memory array, this architecture may also be referred to as a CMOS-Under-Array (CUA) structure.

Referring to FIG. 1A, a stop layer ESL is formed on the stack structure SK1. The material of the stop layer ESL is different from the material of the insulating layer 92, and is different from the material of the conductive layer 94. The composition of the material of the stop layer ESL includes carbon, aluminum or a combination thereof. The stop layer ESL is, for example, carbon-doped polysilicon, carbon-boron-doped polysilicon, carbon-phosphorus-doped polysilicon, aluminum oxide, or a combination thereof. In some embodiments, the stop layer ESL and the conductive layer 94 have the same base material, but have different dopants. For example, the stop layer ESL is carbon-doped polysilicon, carbon-boron-doped polysilicon, and the conductive layer 94 is boron-doped polysilicon or phosphorus-doped polysilicon. The thickness of the stop layer ESL is, for example, 400 angstroms to 800 angstroms.

Referring to FIG. 1A, a stack structure SK2 is formed on the stop layer ESL. The stack structure SK2 includes a plurality of insulating layers 102 and a plurality of interlayers 104 stacked alternately in the Z direction. The insulating layer 102 and the interlayer 104 have different materials. In one embodiment, the material of the insulating layer 102 includes silicon oxide, and the material of the interlayer 104 includes silicon nitride. The thickness of the insulating layer 102 and the interlayer 104 are, for example, 400 angstroms to 450 angstroms, respectively. In some embodiments, the thickness of the stop layer ESL is less than 2.1 times the thickness of the bottommost insulating layer 102₁ of the stack structure SK2. For example, the thickness of the bottommost insulating layer 102₁ and the thickness of the stop layer ESL have a ratio of 1:1 to 1:2.

Referring to FIG. 1A, the interlayer 104 and the insulating layer 102 of the stack structure SK2 are patterned to form a staircase structure (not shown). In some embodiments, the staircase structure may be formed through a multi-stage patterning process, but the disclosure is not limited thereto. The patterning process may include processes such as lithography, etching, and trimming. After that, a dielectric layer (not shown) is formed over the substrate 100 to cover the staircase structure. The material of the dielectric layer is, for example, silicon oxide. The method of forming the dielectric layer includes, for example, forming a dielectric material layer to fill and cover the staircase structure.

Referring to FIG. 1A, a patterning process is performed to remove part of the stack structure SK2, part of the stop layer ESL and part of the stack structure SK1 to form one or more opening 106 passing through the stack structure SK2, the stop layer ESL and stack structure SK1. In one embodiment, the opening 106 may have slightly inclined sidewalls, as shown in FIG. 1A. In another embodiment, the opening 106 may have substantially vertical sidewalls (not shown). In one embodiment, the opening 106 is also referred to as a vertical channel (VC) opening. In one embodiment, the opening 106 may be formed through a one-stage lithography and etching process. In another embodiment, the opening 106 may be formed through multi-stage lithography and etching processes. Then a vertical channel pillar CP is formed in opening 106. The vertical channel pillar CP may be formed by the method described below.

First, referring to FIG. 1A again, a charge storage structure 108 is formed on the sidewall of the opening 106. The charge storage structure 108 may be a composite layer. For example, the charge storage structure 108 includes a tunneling layer (or referred to as an energy gap engineering tunneling dielectric layer) 108₁, a charge storage layer 108₂, and a blocking layer 108₃. In one embodiment, the tunneling layer 108₁ is an oxide, the charge storage layer 108₂ is a nitride, and the blocking layer 108₃ is an oxide.

Next, referring to FIG. 1A again, a channel pillar 110 is formed on the charge storage structure 108. In an embodiment, the material of the channel pillar 110 includes polysilicon. In an embodiment, the channel pillar 110 covers the charge storage structure 108 on the sidewall of the opening 106 and also covers the bottom surface of the opening 106. Next, an insulating pillar 112 is formed at the lower portion of the opening 106. In an embodiment, the material of the insulating pillar 112 includes silicon oxide. Afterwards, a conductive plug 114 is formed at the upper portion of the opening 106, and the conductive plug 114 is in contact with the channel pillar 110. In an embodiment, the material of the conductive plug 114 includes polysilicon. The channel pillar 110, the insulating pillar 112, and the conductive plug 114 may be collectively referred to as a vertical channel pillar CP. The charge storage structure 108 surrounds the vertical outer surface of the vertical channel pillar CP.

Referring to FIG. 1B, an insulating cap layer 115 is formed on the stack structure SK2. The stack structure SK2 and the insulating cap layer 115 may be collectively referred to as a stack structure SK3. Afterwards, a lithography and etching process is performed on the stack structure SK3 to form a plurality of trenches 116. The trench 116 extends in the X direction and passes through the stack structure SK3, and divides the stack structure SK3 into a plurality of block B (e.g., a block B1, a block B2, and a block B3). In one embodiment, the trench 116 may have slightly inclined sidewalls, as shown in FIG. 1B. In another embodiment, the trench 116 may have substantially vertical sidewalls (not shown). The trench 116 exposes the sidewalls of the insulating cap layer 115, the interlayer 104, the insulating layer 102, the stop layer ESL, and the surface of the stop layer ESL.

Referring to FIG. 1B, during the etching process, the stop layer ESL may be used as an etching stop layer. There is a high etching selectivity ratio of the insulating layer 102 and the stop layer ESL. For example, in the embodiment of the disclosure, the etching selectivity ratio of the insulating layer 102 and the stop layer ESL is, for example, 20 to 60. This ratio is much larger than the etching selectivity ratio (e.g., 10 to 20) of the insulating layer 102 and the doped (boron or phosphorus) polysilicon. Therefore, in the embodiment of the disclosure, the stop layer ESL may be used as an etching stop layer, and the trenches 116 formed in this etching stage may stop at the stop layer without penetrating the stop layer ESL.

Referring to FIG. 1C, the etching process is continued to remove the stop layer ESL at the bottom of the trench 116 to form the trench 116a. The bottom of the trench 116a exposes the topmost insulating layer 92₁ of the stack structure SK1, as shown in FIG. 1C. Referring to FIG. 1D, the etching process is continued to remove the topmost insulating layer 92₁ at the bottom of the trench 116a to form the trench 116b, as shown in FIG. 1D.

Referring to FIG. 1D, a protection layer 117 is formed on the stack structure SK3 and in the trench 116b. The protection layer 117 includes a dielectric material different from the insulating layer 102, such as silicon nitride or a silicon oxide/silicon nitride/silicon oxide composite layer.

Referring to FIG. 1E, an anisotropic etching process is performed to remove the protection layer 117 on the bottom of the trench 116b to form the protection layer 117a, and expose the bottom of the trench 116b to expose the conductive layer 94₁ of the stack structure SK1.

Referring to FIG. 1F, a selective etching process is performed to remove the conductive layer 94₁ to form a horizontal opening 123, as shown in FIG. 1F. Referring to FIG. 1G, the selective etching process is continued to remove the insulating layers 92₁ and 92₂ exposed by the horizontal opening 123 to form the horizontal opening 123a, as shown in FIG. 1G. A portion of charge storage structure 108 is also removed and a portion of channel pillar 110 is exposed to the horizontal opening 123a.

Referring to FIG. 1H, a conductive layer 93, for example a doped polysilicon layer, is filled in the trench 116b and the horizontal opening 123a. The conductive layer 93 in the horizontal opening 123a and the conductive layer 94₂ below the conductive layer 93 collectively form the conductive layer 120. The conductive layer 120 may be used as a source line. The method for forming the conductive layer 93 is, for example, to fill a conductive material layer on the stack structure SK3 and in the trench 116b and the horizontal opening 123a, and then the conductive material layer is etched back to remove the conductive material layer on the stack structure SK3 and in the trench 116b. The material of the conductive layer 93 is, for example, doped polysilicon. The dopant of doped polysilicon may include an element of the group III (e.g., boron) or an element of the group V (e.g., phosphorus). The conductive layer 93 directly contacts the exposed portion of channel pillar 110.

Referring to FIG. 1I and FIG. 1J, a gate replacement process is performed to replace the interlayers 104 with gate conductive layers 126. First, referring to FIG. 1I, a selective etching process is performed through the trench 116b, so that the protection layer 117 is first etched, and then the interlayer 104 is etched to form a plurality of horizontal openings 121. The horizontal opening 121 exposes part of the sidewalls of the charge storage structure 108 and the upper and lower surfaces of the insulating layer 102. The selective etching process may be isotropic etching, for example, a wet etching process. The etchant used in the wet etching process is, for example, hot phosphoric acid.

Referring to FIG. 1J, then, a conductive layer 126 is formed in the trench 116b and the horizontal opening 121. The conductive layer 126 includes, for example, a barrier layer 122 and a metal layer 124. In an embodiment, the material of the barrier layer 122 includes titanium (Ti), titanium nitride (TiN), tantalum (Ta), tantalum nitride (TaN), or a combination thereof, and the material of the metal layer 124 includes tungsten (W).

The formation method of the barrier layer 122 and the metal layer 124 is, for example, filling a barrier material layer and a metal material layer on the stack structure SK3 and in the trench 116b and the horizontal opening 121. Next, an etch back process is performed to remove the barrier material layer and a metal material layer above the stack structure SK3 and in the trench 116b. The gate conductive layer 126, the insulating layer 102 and the insulating cap layer 115 form a gate stack structure GSK.

Referring to FIG. 1K, a plurality of conductive slit structures SLT are formed in the trench 116b to land on the conductive layer 94₂ and electrically connect to the conductive layer 94₂. The conductive slit structure SLT may include spacers 128 and a conductive filling layer 130. The spacers 128 are formed on the sidewalls of the trench 116b. The conductive filling layer 130 is filled into the remaining space of the trenches 116b. The spacers 128 include a dielectric material, such as silicon oxide. The spacers 128 are formed, for example, by forming a spacer material layer on the gate stack structure GSK and to fill in the trenches 116b, and then performing an etch back process to remove the spacer material layer above the gate stack structure GSK3 and the bottom of the trenches 116b. The material of the conductive filling layer 130 includes doped polysilicon or tungsten. The method for forming the conductive filling layer 130 is, for example, to fill a conductive material layer on the gate stack structure GSK and the remaining space of the trench 116b, and then perform an etching back process to remove the conductive material layer on the gate stack structure GSK.

Thereafter, subsequent related manufacturing processes may be performed to complete the production of the memory device.

FIG. 2 is a partial enlarged view of FIG. 1K.

Referring to FIG. 2, in the embodiment of the disclosure, the memory device includes a stop layer ESL provided between the conductive layer 120 and the gate stack structure GSK. The material of the stop layer ESL is different from that of the conductive layer 120 and different from the insulating layer 102 and the gate conductive layer 126. In the process of forming the trench 116 (shown in FIG. 1B), the insulating layer 102 and the stop layer ESL have a high etch selectivity. Therefore, a thinner stop layer ESL may be used as the etch stop layer. In some examples, the ratio of the thickness W₂ of the insulating layer 102₁ of the gate stack structure GSK to the thickness W₁ of the stop layer ESL is, for example, 1:1 to 1:2.

Since the thickness W₁ of the stop layer ESL is thin, the distance D between the conductive layer 120 and the bottommost gate conductive layer 126₁ of the gate stack structure GSK is small. Therefore, during the subsequent thermal process, the dopant 93i in the conductive layer 93 may first diffuse laterally to the channel pillar 110 at the same level as the conductive layer 93, and then the dopant 93i move vertically upwards by a smaller distance D to diffuse to the channel pillar 110 at the same level as the bottommost gate conductive layer 126₁. Therefore, the time of the thermal process may be shortened, and the thermal budget may be reduced. The thermal process may be carried out at any stage. In some embodiments, the thermal process is performed before the gate replacement process. In other embodiments, the thermal process is performed after the gate replacement process and before the formation of the conductive slit structure SLT. In still other embodiments, the thermal process is performed after forming the conductive slit structure SLT. The temperature of the thermal process is, for example, 700° C. to 900° C. The time of the thermal process is, for example, 20 minutes to 60 minutes.

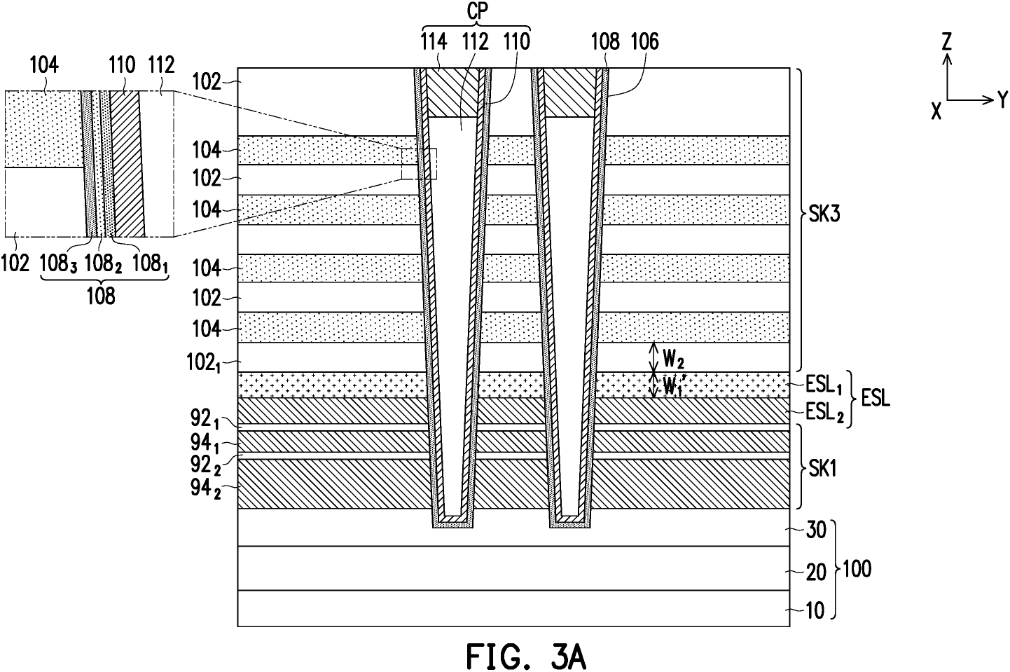

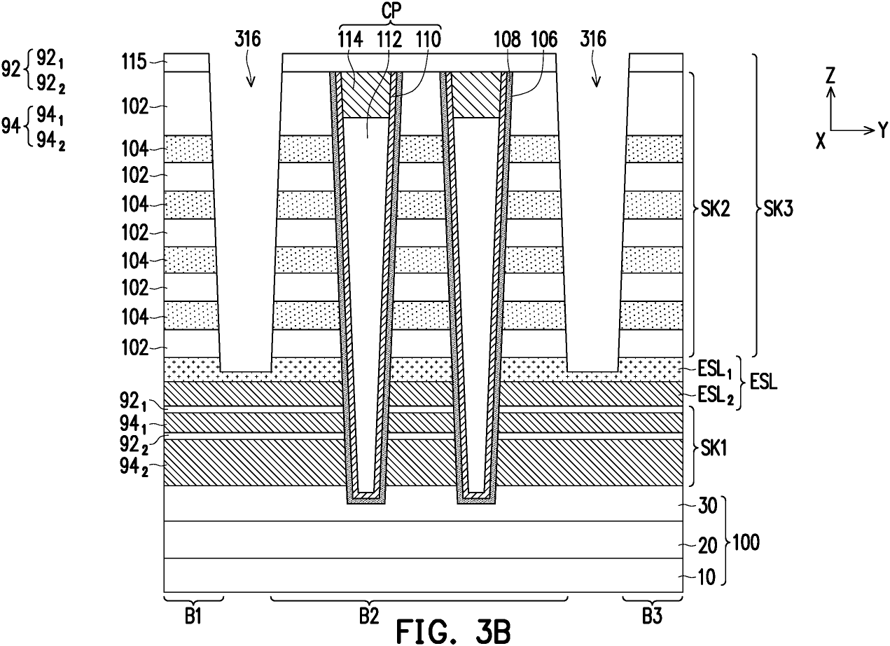

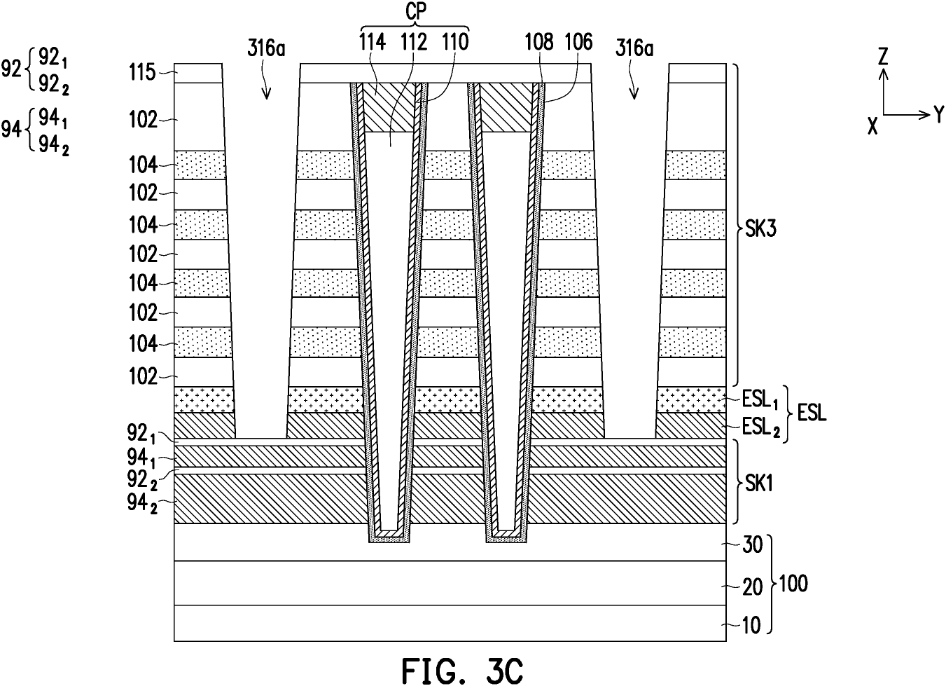

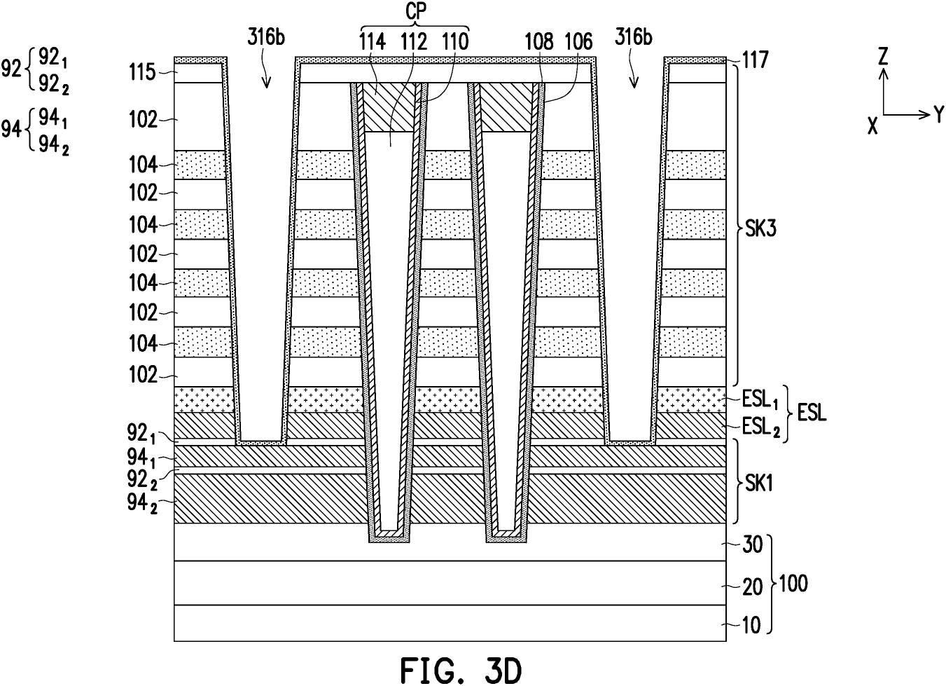

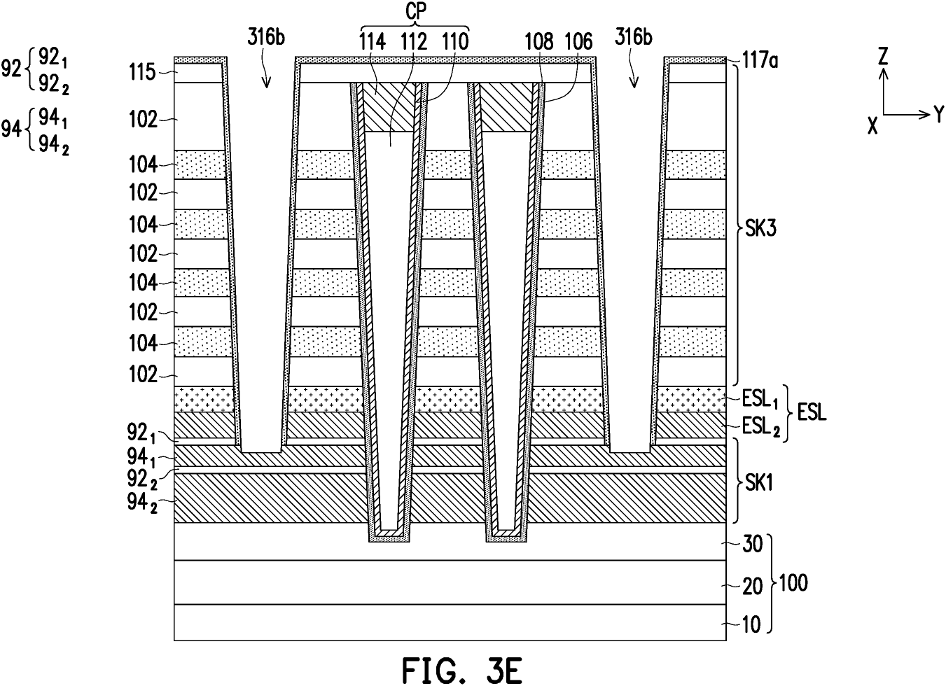

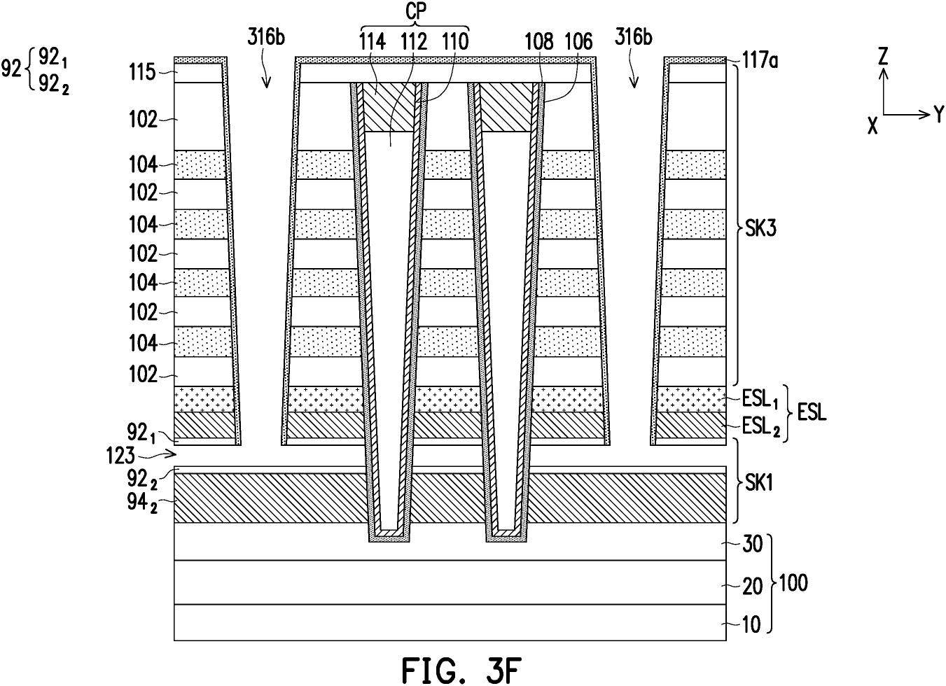

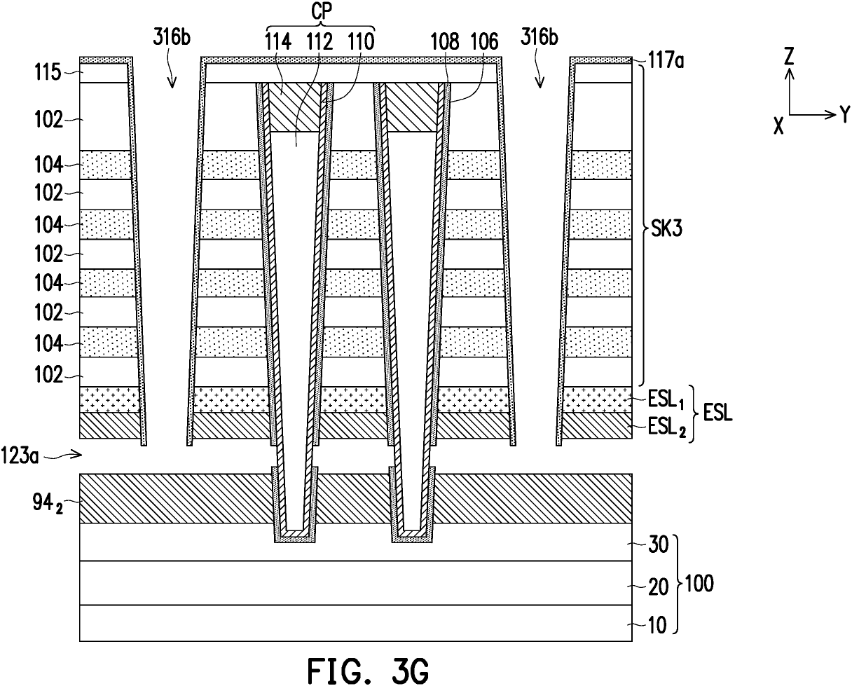

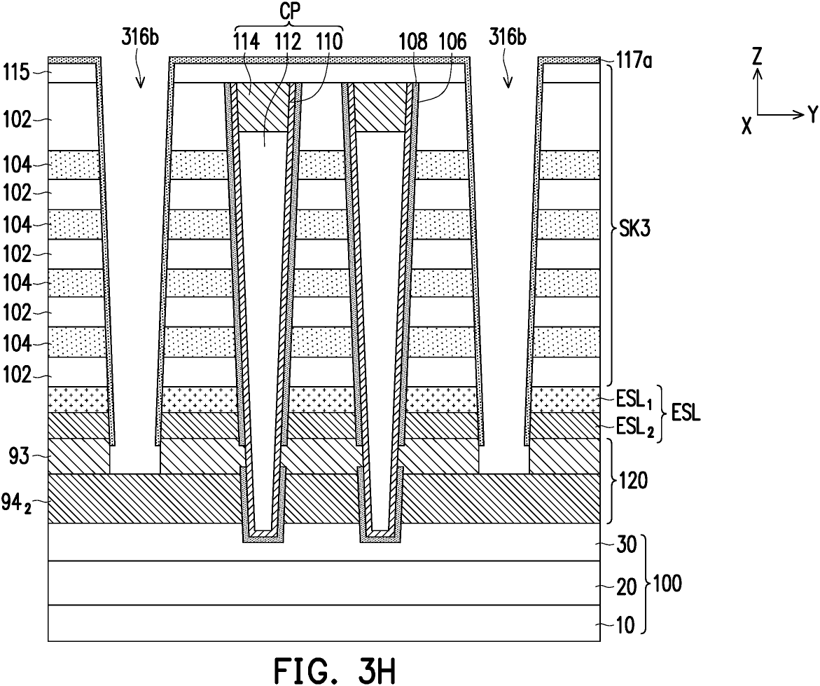

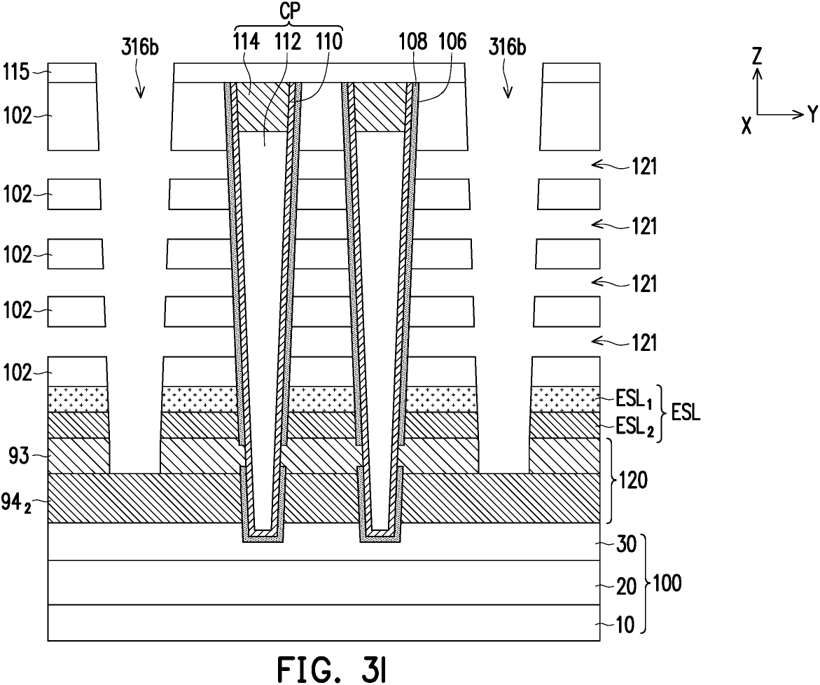

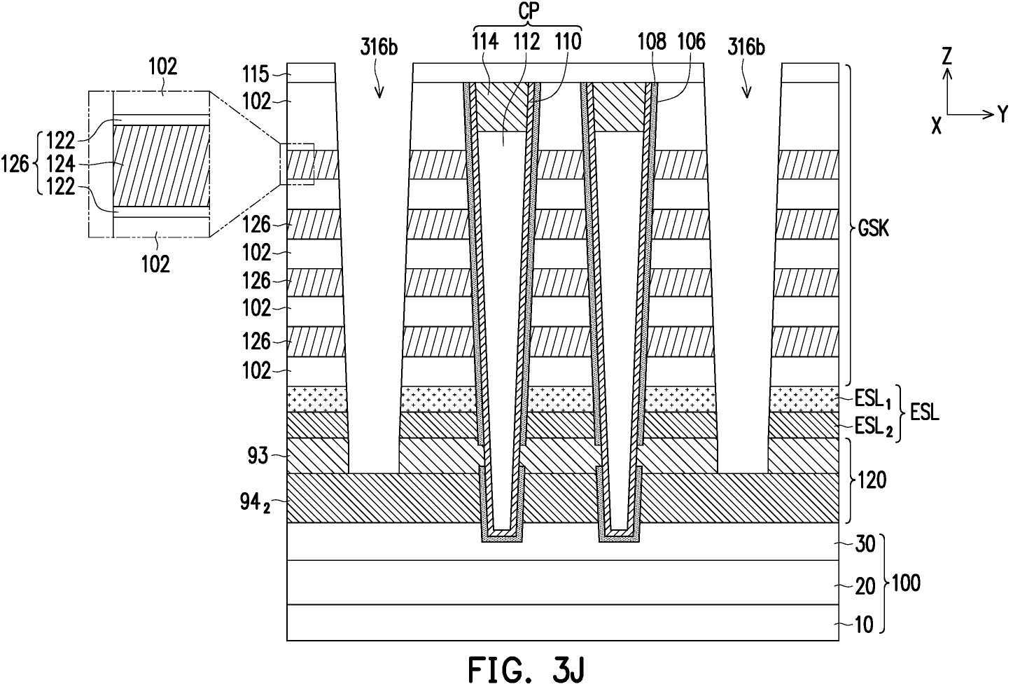

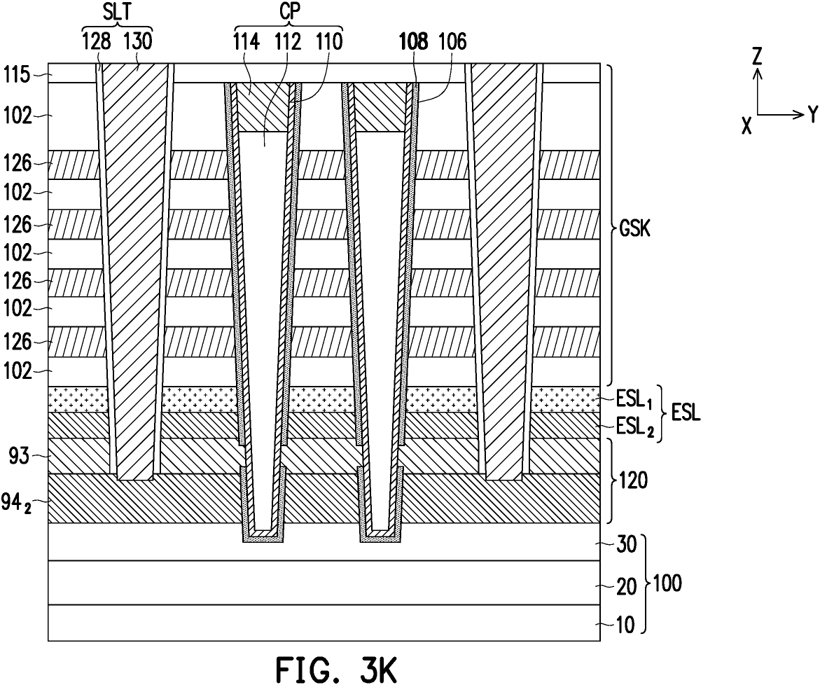

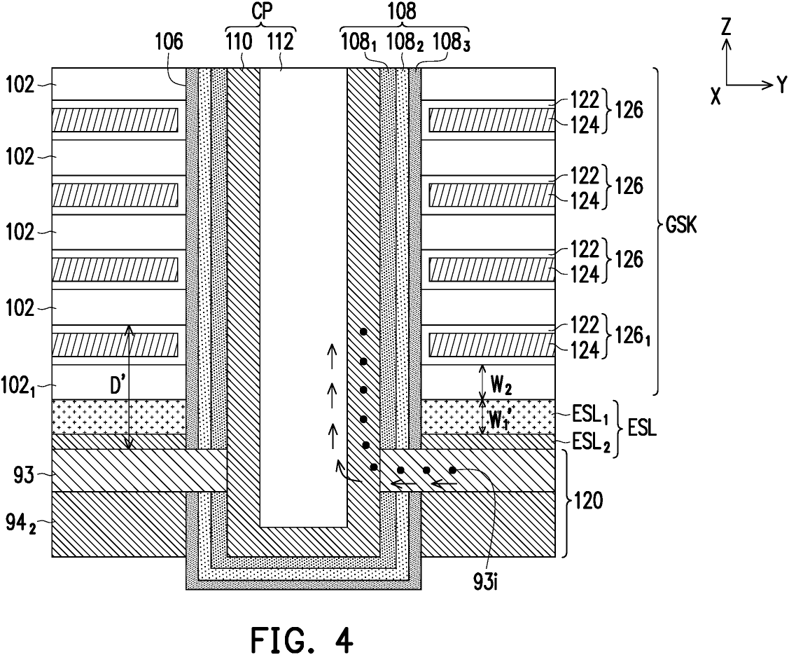

The stop layer of the disclosure may be a single layer (as described in the above embodiment). In another embodiment, the stop layer may also be multiple layers, as shown in FIGS. 3A to 3K.

FIGS. 3A to 3K are schematic cross-sectional views showing a method for manufacturing a three-dimensional memory device according to an embodiment of the disclosure. Referring to FIG. 3A, a stack structure SK1, a stop layer ESL, and a stack structure SK2 are formed on the substrate 100. The substrate 100, the stack structure SK1, and the stack structure SK2 may be the same as the substrate 100, the stack structure SK1, and the stack structure SK2 in the above embodiment. The stop layer ESL of this embodiment includes a lower stop layer ESL₂ and an upper stop layer ESL₁. The material of the lower stop layer ESL₂ is different from the material of the upper stop layer ESL₁. The material of the lower stop layer ESL₂ is, for example, doped polysilicon. The dopant of doped polysilicon may include be an element of the group III (e.g., boron) or an element of the group V (e.g., phosphorus). In some embodiments, the lower stop layer ESL₂ and the conductive layer 94 have the same base material, and have the same dopant. The upper stop layer ESL₁ is, for example, carbon-doped polysilicon, carbon-boron-doped polysilicon, carbon-phosphorus-doped polysilicon, aluminum oxide, or a combination thereof. In some embodiments, the upper stop layer ESL₁ and the lower stop layer ESL₂ have the same base material, but have different dopants. For example, the upper stop layer ESL₁ is carbon-doped polysilicon, carbon-boron-doped polysilicon, and the lower stop layer ESL₂ is boron-doped polysilicon or phosphorus-doped polysilicon.

In the process of forming the trench 116 (as shown in FIG. 3B), the insulating layer 102 and the upper stop layer ESL₁ have a high etch selectivity. Therefore, a thin upper stop layer ESL₁ may be used as the etch stop layer. In some examples, the ratio of the thickness W₂ of the insulating layer 102₁ of the bottommost insulating layer 102₁ of the gate stack structure GSK to the thickness W1′ of the stop layer ESL is, for example, 1:1 to 1:2.

Since the thickness W1′ of the stop layer ESL is thin, the distance D′ between the conductive layer 120 and the bottommost gate conductive layer 126₁ of the gate stack structure GSK is relatively small. Therefore, during the subsequent thermal process, the dopant in the conductive layer 93 may diffuse laterally to the channel pillar 110 at the same level, and then diffuse vertically upwards to the channel pillar 110 at the same level as the bottommost gate conductive layer 126₁. Therefore, the channel pillar 110 corresponding to the bottommost gate conductive layer 126₁ may have the desired doping concentration.

In the foregoing embodiments, the 3D flash memory structure is a 3D NAND memory structure, but the disclosure is not limited thereto. In other embodiments, the 3D flash memory structure may be a 3D AND memory structure or 3D NOR memory structure.

In the embodiment of the disclosure, the stop layer may be used as an etching stop layer when forming the trench for the conductive slit structure. Since the stop layer has high etching selectivity to the insulating layer, the thickness of the stop layer is quite thin. As a result, the distance between the bottommost gate conductive layer and the conductive layer below the stop layer may be reduced, so that the dopant in the conductive layer below the g stop layer may move up by a smaller distance and diffuse to the channel pillar corresponding to the select gate to have an appropriate threshold voltage. Therefore, in the embodiment of the disclosure, a thin stop layer with a high selectivity may be used to reduce the time of the thermal process and reduce the thermal budget.

What is claimed is:

1. A memory device comprising:
a substrate;
a metal interconnection structure, disposed over the substrate;
a conductive layer, disposed on the metal interconnection structure;
a stop layer, disposed on the conductive layer;
a gate stack structure, disposed on the stop layer, wherein the gate stack structure includes a plurality of insulating layers and a plurality of gate conductive layers that alternate with each other, wherein a ratio of a thickness of a bottommost insulating layer of the gate stack structure to a thickness of the stop layer is 1:1 to 1:2;
a channel pillar, extending through the gate stack structure and the stop layer, and connected to the conductive layer; and
a charge storage structure, disposed between sidewalls of the channel pillar and the multiple gate conductive layers.

2. The memory device according to claim 1, wherein the material of the stop layer is different from the material of the conductive layer.

3. The memory device according to claim 1, wherein a dopant of the stop layer is different from a dopant of the conductive layer.

4. The memory device according to claim 1, wherein a composition of a material of the stop layer comprises carbon, aluminum or a combination thereof.

5. The memory device according to claim 4, wherein the stop layer comprises carbon-doped polysilicon, carbon-boron-doped polysilicon, carbon-phosphorus-doped polysilicon, aluminum oxide, or a combination thereof.

6. The memory device according to claim 1, wherein the stop layer includes at least one layer.

7. The memory device according to claim 1, wherein a thickness of the stop layer is 400 angstroms to 800 angstroms.

8. The memory device according to claim 1 further comprising a conductive slit structure, wherein the conductive silt structure extends through the gate stack structure and the stop layer, and is electrically connected to the conductive layer.

9. The memory device according to claim 1, wherein the conductive layer comprises:
a lower conductive layer disposed on the interconnection structure; and
an upper conductive layer disposed between the lower conductive layer and the stop layer, and electrically connected to the channel pillar.

10. A memory device comprising:
a substrate;
an interconnection structure, disposed over the substrate;
a conductive layer, disposed on the interconnection structure;
a stop layer, disposed on the conductive layer;
a gate stack structure, disposed on the stop layer, wherein the gate stack structure includes a plurality of insulating layers and a plurality of gate conductive layers that alternate with each other, wherein a material of the stop layer is different from a material of the conductive layer and a material of the insulating layer;
a channel pillar, extending through the gate stack structure and the stop layer, and connected to the conductive layer; and
a charge storage structure, disposed between sidewalls of the channel pillar and the multiple gate conductive layers.

11. The memory device according to claim 10, wherein a composition of a material of the stop layer comprises carbon, aluminum or a combination thereof.

12. The memory device according to claim 10, wherein the stop layer comprises carbon-doped polysilicon, carbon-boron-doped polysilicon, carbon-phosphorus-doped polysilicon, aluminum oxide, or a combination thereof.

13. The memory device according to claim 10, wherein a ratio of a thickness of a bottommost insulating layer of the gate stack structure to a thickness of the stop layer is 1:1 to 1:2.

14. A method for manufacturing a memory device comprising:
forming an interconnection structure on a substrate;
forming a first stack structure on the interconnection structure, wherein the first stack structure comprises a plurality of first conductive layers and a plurality of first insulating layers that alternate with each other;
forming a stop layer on the first stack structure;
forming a second stack structure on the stop layer, wherein the second stack structure comprises a plurality of second insulating layers and a plurality of interlayers that alternate with each other;
forming a charge storage structure and a channel pillar in the second stack structure, the stop layer and the first stack structure;
forming a trench in the second stack structure by using the stop layer as an etching stop layer;
removing the stop layer at a bottom of the trench, the plurality of first insulating layers of the first stack structure, and a first conductive layer between the plurality of first insulating layers to form a first horizontal opening, wherein the first horizontal opening exposes sidewalls of the channel pillar;
forming a second conductive layer in the first horizontal opening, wherein the second conductive layer is electrically connected to the sidewalls of the channel pillar;
removing the plurality of interlayers of the second stack structure to form a plurality of second horizontal openings;
forming a plurality of gate conductive layers in the plurality of second horizontal openings; and
performing a thermal process to diffuse a dopant in the second conductive layer into the channel pillar.

15. The method of manufacturing a memory device according to claim 14, wherein the stop layer includes a material different from a material of the first conductive layer.

16. The method of manufacturing a memory device according to claim 14, wherein a dopant of the stop layer is different from a dopant of the second conductive layer.

17. The method of manufacturing a memory device according to claim 14, wherein a composition of a material of the stop layer comprises carbon, aluminum, or a combination thereof.

18. The method of manufacturing a memory device according to claim 17, wherein the stop layer comprises carbon-doped polysilicon, carbon-boron-doped polysilicon, carbon-phosphorus-doped polysilicon, aluminum oxide, or a combination thereof.

19. The method for manufacturing a memory device according to claim 17, wherein the stop layer comprises multiple layers.

20. The method for manufacturing a memory device according to claim 14 further comprising forming a conductive slit structure in the trench, wherein a bottom of the conductive slit structure lands on the first conductive layer.
